(19) United States
(12) Patent Application Publication
(10) Pub. No.: US 2007/0281476 A1
(43) Pub. Date: Dec. 6, 2007

(54) Methods for forming thin copper films and structures formed thereby

(76) Inventors: Adrien R. Lavoie, Beaverton, OR (US); Juan E. Dominguez, Portland, OR (US); John J. Plombon, Portland, OR (US); Valery M. Dubin, Portland, OR (US); Harsono S. Simka, Saratoga, CA (US); Joseph H. Han, San Jose, CA (US); Bryan C. Hendrix, Danbury, CT (US); Gregory T. Stauf, New Milford, CT (US); Jeffrey F. Roeder, Brookfield, CT (US); Tiannu Chen, Rocky Hill, CT (US); Chongying Xu, New Milford, CT (US); Thomas H. Baum, New Fairfield, CT (US)

Correspondence Address: INTEL CORPORATION;c/o INTELLEVATE, LLC, P.O. BOX 52050, MINNEAPOLIS, MN, 55402, US

(21) Appl. No.: 11/446,339

(22) Filed: Jun. 2, 2006

(51) Int. Cl. H01L 21/44

(52) U.S. Cl. 438/687

(57) ABSTRACT

Methods and associated structures of forming a microelectronic structure are described. Those methods may comprise forming a thin conformal copper layer on a surface by utilizing a formation temperature below about 125 degrees Celsius.

### BACKGROUND OF THE INVENTION

Thin copper films may be formed by using such techniques as atomic layer deposition (ALD) and chemical vapor deposition (CVD), which may employ precursors requiring high vaporization temperatures and/or fluorine containing ligands, for example. In some cases, such copper films may be susceptible to agglomeration that may be caused during formation and/or during a subsequent thermal anneal processing. Such films may also suffer from poor adhesion to the underlying substrate.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1f represent cross-sections of structures that may be formed when carrying out an embodiment of the methods of the present invention.

FIG. 2 represents a flow chart according to an embodiment of the methods of the present invention.

FIG. 3a-3b represent flow charts according to an embodiment of the methods of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure, such as a copper interconnect structure, are described. Those methods may comprise forming a thin conformal copper layer on a surface by utilizing a formation temperature below about 125 degrees Celsius. The thin conformal copper layer may possess significantly improved adhesion characteristics, thus substantially preventing delamination from a surface, for example.

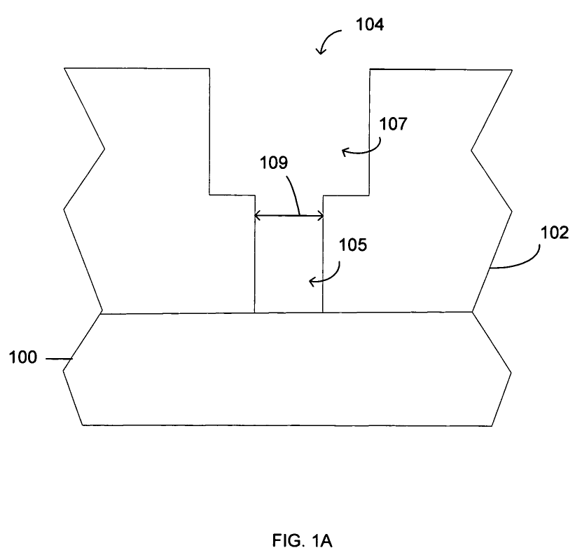

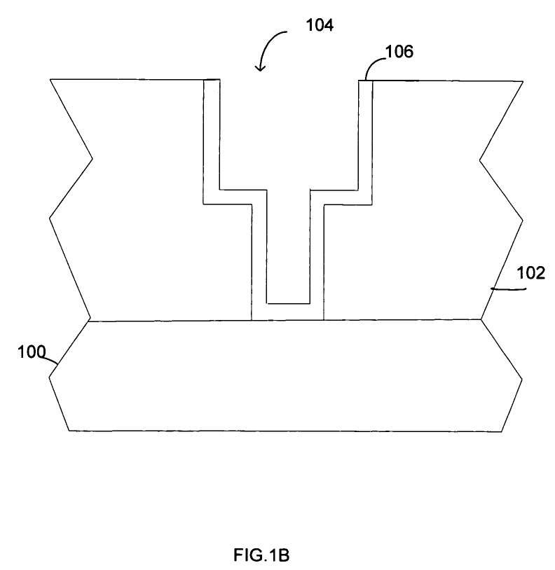

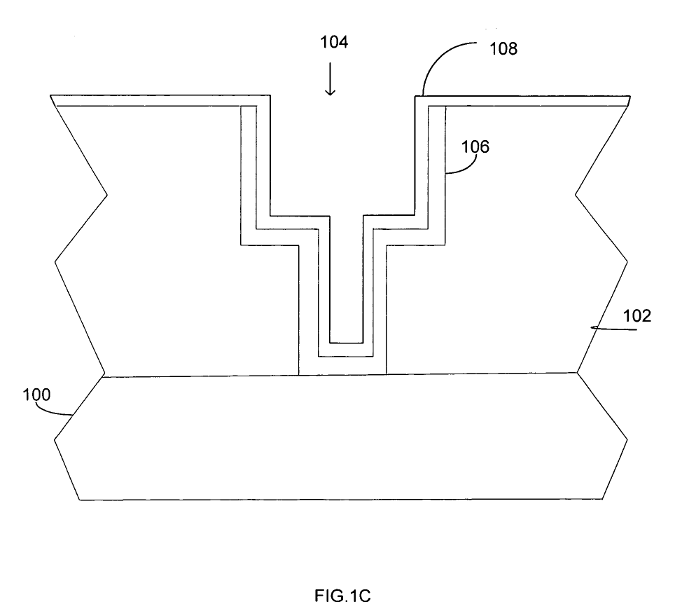

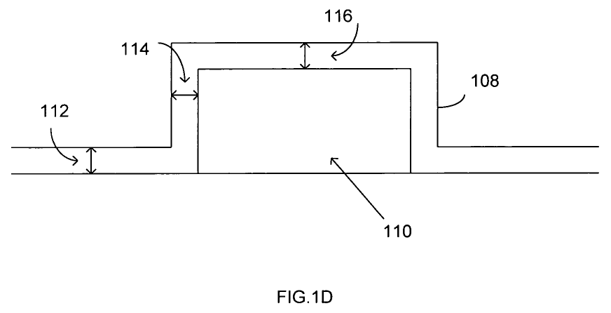

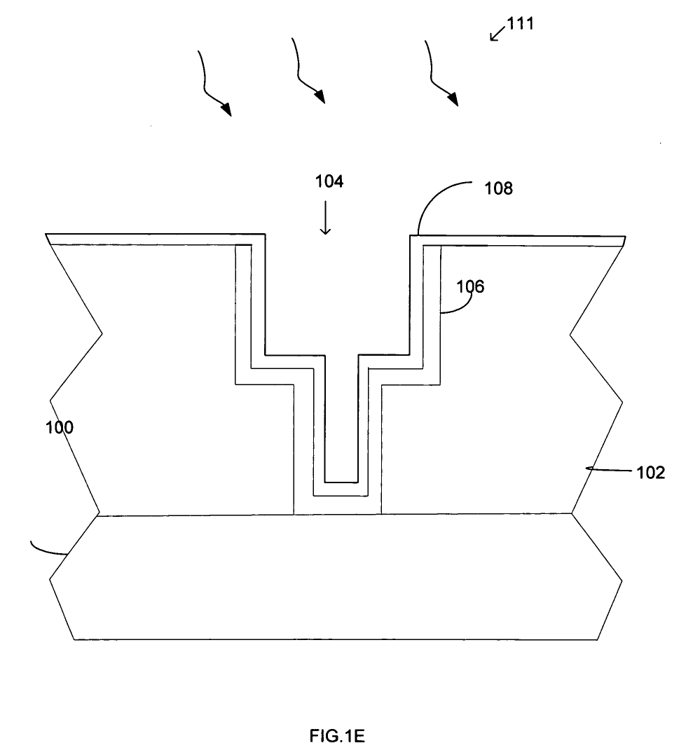

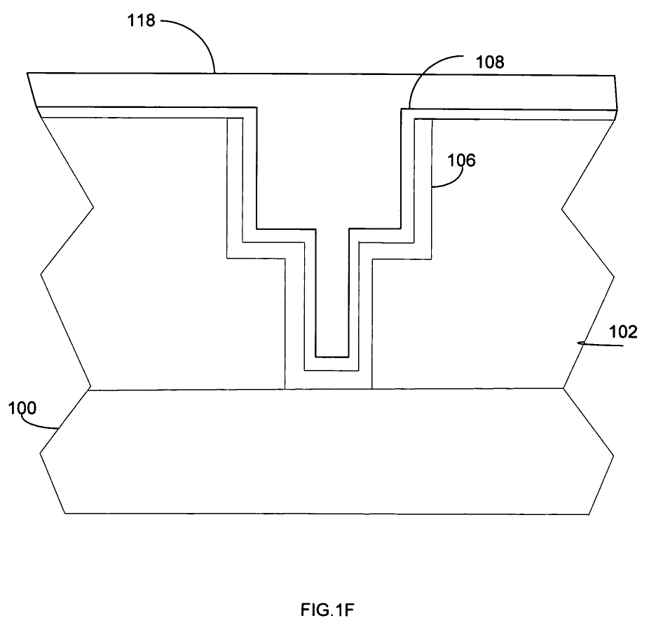

In an embodiment of the method of the present invention, as illustrated by FIGS. 1a-1f, a dielectric layer 102 may be disposed on a substrate 100 (FIG. 1a). The substrate 100 may comprise materials such as silicon, silicon-on insulator, germanium, indium antimonide, lead telluride, indium arsenide, indium phosphide, gallium arsenide, or gallium antimonide. Although several examples of materials from which the substrate 100 may be formed are described here, any material that may serve as a foundation upon which a microelectronic device may be built falls within the spirit and scope of the present invention.

The dielectric layer 102 may comprise a variety of materials, thicknesses or multiple layers of material. By way of illustration and not limitation, the dielectric layer 102 may include silicon dioxide (preferred), organic materials or inorganic materials. Although a few examples of materials that may be used to form the dielectric layer 102 are described here, that layer may be made from other materials that may serve to separate and insulate conductive layers from each other, for example. In one embodiment, the dielectric layer 102 may comprise a low k dielectric material, and may comprise a dielectric constant below about 3.0.

The dielectric layer 102 may comprise at least one opening 104. In one embodiment, the at least one opening 104 may comprise a via portion 105, and a trench portion 107, which may comprise a portion of a damascene structure which may be used to connect conductive layers to each other within a microelectronic device, for example, as is known by those skilled in the art. In one embodiment, the at least one opening 104 may comprise a minimum width 109 (by illustration and not limitation, the minimum width 109 may be located in the via portion 105). In one embodiment, the minimum width 109 may be less than about 100 nm, and in some cases may be less than about 50 nm.

In one embodiment, a barrier layer 106 may be deposited onto the at least one opening 104 (FIG. 1b) and may line the at least one opening 104. Those skilled in the art will appreciate that the barrier layer 106 may be formed from a variety of materials, thicknesses or multiple layers of material. In one embodiment, the barrier layer 106 can include any one of the following materials: tantalum, tungsten, titanium ruthenium and their alloys with light elements such as, but not limited to nitrogen, silicon and carbon, and combinations thereof. Although a few examples of materials that may be used to form the barrier layer 106 are described here, that layer may be made from other materials that serve to prevent the diffusion of a conductive material across the barrier layer 106. In one embodiment, the barrier layer 106 can range from a monolayer to about 500 angstroms.

In one embodiment, a thin conformal copper layer 108 may be formed on the barrier layer 106 (FIG. 1c). In general, the thin conformal copper layer 108 may be formed on any surface according to the particular application, and need not be limited to formation on the barrier layer 106. In one embodiment, the thin conformal copper layer 108 may be formed utilizing a CVD and/or an ALD process. In one embodiment, the temperature of formation of the thin conformal copper layer 108 may comprise a temperature below about 125 degrees Celsius, and in some cases may be below about 120 degrees Celsius. In one embodiment, the thin conformal copper layer 108 may serve to activate a surface, such as the surface of the barrier layer 106, in order to prepare for or enable deposition of another layer, such as a copper plated layer, for example. In one embodiment, the thin conformal copper layer 108 may comprise a seed layer, as is known in the art.

In one embodiment, the thin conformal copper layer 108 may be formed by reacting at least one organometallic precursor with at least one co-reactant. In one embodiment, the at least one organometallic precursor may comprise at least one of a copper containing amidinate. In one embodiment, the copper containing amidinate may comprise such compounds as copper-DMAPA (2-dimethylamino-N,N′ diisopropyl amidinate, also referred to as N—N′-diisopropyl-N″,N″-dimethylguanidinate), copper-MOPA (2-methoxy-N,N′-diisopropyl amidinate), copper-EMAPA (2-ethylmethylamino-N—N′-diisopropyl amidinate), copper-BTMSAPA (2-bis(trimethylsilyl)amino-N,N′-diisopropyl amidinate), copper-HPA (N,N′-diisopropyl amidinate), copper-DMAtBA (2-dimethylamino-N,N′-di-tert-butyl amidinate), copper-DMABTMSA (2-dimethylamino-N,N′-di-trimethlysilyl amidinate), copper-EtOPA (2-ethoxy-N,N′-diisopropyl amidinate), copper-BOPA (2-tert-butoxy diisopropyl amidinate), copper-DMotBA (2-methoxy-N,N′-di-tert-butyl amidinate) and combinations thereof.

In one embodiment, the thin conformal copper layer 108 may be formed by reacting and/or utilizing at least one organometallic precursor delivered in a carrier gas, but without any co-reactants. In one embodiment, the at least one organometallic precursor may comprise at least one of a copper(I) and/or copper(II) molecule containing amidinate ligand. In another embodiment, the copper containing amidinate may comprise such compounds as copper-DMAPA copper-DMOPA, copper-EMAPA, copper-BTMSAPA, copper-HPA, copper-DMAtBA, copper-DMABTMSA, copper-MOPA, copper-EtOPA, copper-BOPA (2-tert-butoxy-diisopropal amidinate), copper-MOtBA, and copper-MOTMSA.

In another embodiment, the organometallic precursor may comprise copper containing amino-alkoxy compounds such as copper-DMAEO (2-(N,N′-dimethylamino)ethoxy-) and/or copper-DMAIPO (3-(N,N′-dimethylamino)-2-propoxy-), as well as copper containing Pyrazolato compounds, such as, but not limited to copper Pyrazolato (Cu(I)[(3,5 ditriflouromethyl)pyrazolato]) and combinations thereof. In one embodiment, the organometallic precursor may comprise a low volatility organometallic precursor, wherein the organometallic precursor may become volatile below about 125 degrees Celsius.

In one embodiment, the at least one co-reactant may comprise an amine containing co-reactant, such as but not limited to NH₃, NEt₃, HNEt₂, BuNH₂ and combinations thereof. In another embodiment, the co-reactant may comprise non-amine containing compounds (such as reducing agents for example) such as but not limited to B₂H₆, SiH₄, GeH₄, SnH₄, AlH₃, H₂ and combinations thereof.

The particular process parameters may vary depending upon the particular application, but in one example, copper-DMAPA may be reacted with NH₃ in an ALD and/or CVD process, which may use a plasma (in the precursor, co-reactant or both), in some embodiments, although it is not necessary). In one embodiment, the ALD process may comprise growing a film layer by layer by exposing a surface/substrate to alternating pulses of the organometallic precursor and the co-reactant, wherein each pulse may include a self-limiting reaction and may result in a controlled deposition of a film. In one embodiment, a growth cycle for the thin conformal copper layer 108 may comprise two pulses, wherein one pulse may comprise the organometallic precursor and one pulse may comprise the co-reactant. In one embodiment, each pulse may be separated by an inert gas purge of a reaction chamber in order to remove compounds and reaction intermediate existing in the chamber.

In one embodiment, a deposition temperature for an ALD and/or CVD process may range from about 80 degrees to about 125 degrees Celsius, by illustration and not limtation. The pressure may range from about 6 to about 10 Torr, and the molar flow rate of the copper-DMAPA may range from about 40 to about 50 micromoles per minute, and may in some cases utilize an inert carrier gas such as N2 or He, for example . Flow rates for NH3 and He may comprise 200 and 25 sccm respectively.

A growth rate for the thin conformal copper layer 108 grown under these process conditions may range from about 2 to 8 angstroms per minute. In one embodiment, the ALD and/or CVD process may be substantially free of any fluorine, and/or fluorine containing compounds. In one embodiment, plasma processing, such as PECVD (plasma enhanced CVD) and/or PEALD (plasma enhanced ALD) processes may be utilized, according to the particular application. In one embodiment, radical-assisted processing, wherein Hydrogen or other atomic radicals are generated in-situ, may be utilized according to the particular application.

In one embodiment, the thin conformal copper layer 108 may comprise a thickness below about 30 nanometers, and in another embodiment, may comprise a continuous thickness of about between about 2 to about 5 nm. In yet another embodiment, the thickness of the thin conformal copper layer 108 may comprise a range of about 2 to about 200 nm. The thickness of the thin conformal copper layer 108 may vary depending upon the particular application.

In one embodiment, the thin conformal copper layer 108 may comprise a copper percentage (which may comprise units of atomic percent) of about 93 percent, a nitrogen percentage of about 2 percent, a carbon percentage of about 4 percent and an oxygen percentage of about 1 percent. In another embodiment, the percentage of copper may be greater than about 93 percent. In another embodiment, the thin conformal copper layer 108 may comprise between about 90 and 99 percent copper.

In one embodiment, the percentage of nitrogen, carbon and oxygen present in the formed thin conformal copper layer 108 may reflect the use of the organometallic precursors and ammonia containing co-reactants during formation, and their concentrations may be higher than the noise levels of various compositional analysis tools, such as SIMS and XPS, as are known in the art. In one embodiment, the resistivity of the thin conformal copper layer may comprise 7.4 micro-ohm-cm at 10 nm and 27 micro-ohm-cm at 1.7 nm. In one embodiment, the roughness of the thin conformal copper layer 108 may comprise a mean roughness of between about 0.2 and 3 nm.

In one embodiment, the thin conformal copper layer 108 may be substantially conformal. In one embodiment, the thin conformal copper layer 108 may comprise a ratio of a bottom thickness 112 to a side thickness 114 to a top thickness 116 as deposited over a feature 110 of about 1:1:1 (FIG. 1d). The feature 110 may comprise any structure, such as but not limited to a portion of an interconnect structure, that may comprise the thin conformal copper layer 108. In one embodiment, the feature 110 may comprise a metal trace comprising the thin conformal copper layer 108.

In one embodiment, the surface on which the thin conformal copper layer 108 may be deposited, such as but not limited to the surface of the barrier layer 106, may be treated prior to the formation of the thin conformal copper layer 108. In one embodiment, the surface may be exposed to at least one organometallic precursor (similar to the at least one organometallic precursors described previously herein) and at least one co-reactant similar to the at least one co-reactants described previously herein) during the formation of the surface and/or barrier layer 106. In this manner, the surface 106 may become doped and/or functionalized, which may improve the adhesion properties of the thin conformal copper layer 108 to the surface 106, for example.

In another embodiment, the surface 106 may be exposed to at least one of NH₃, NEt₃, HNEt₂, tBuNH₂, B₂H₆, SiH₄, GeH₄, SnH₄, AlH₃ and H₂ prior to the formation of the thin conformal copper layer 108. In this manner, the surface, such as the barrier layer 106 surface, may be chemically modified in order to facilitate adhesion of the thin conformal copper layer 108, for example. In one embodiment, plasma modification of the surface may be used prior to the formation of the thin conformal copper layer 108, which may help densify the substrate surface and/or improve the subsequent copper nucleation process.

Subsequent to formation, the thin conformal copper layer 108 may optionally be exposed to a purification process 111, in which any impurities that may be present within the thin conformal copper layer 108 may be substantially removed (FIG. 1e). In one embodiment, the purification process 111 may comprise exposing the thin conformal copper layer 108 to a CVD process comprising a copper, and an amine containing co-reactant such as but not limited to ammonia, for example, and at least one of H₂, SiH₄, B₂H₆, GeH₄, SnH₄, AlH₃, CO and forming gas. The CVD purification process may comprise a continuous process, as opposed to a pulsed formation process. In another embodiment, the purification process 111 may comprise exposing the thin conformal copper layer 108 to an amine containing co-reactant with a non-amine containing co-reactant.

In another embodiment, the thin conformal copper layer 108 may be exposed to a purification process 111 utilizing an ALD process comprising an amine containing co-reactant and at least one of H₂, SiH₄, B₂H₆, GeH₄, SnH₄, AlH₃ and forming gas. In one embodiment, a pulsed ALD process may be used to purify the thin conformal copper layer 108, wherein the thin conformal copper layer 108 may first be exposed to at least one copper containing organometallic precursor, followed by a purging step, in which the thin conformal copper layer 108 may be exposed to an inert gas, such as argon, for example. The thin conformal copper layer 108 may then be exposed to flow of NH₃, followed by exposing the thin conformal copper layer 108 to a flow of forming gas. The pulsed ALD may be repeated as necessary, depending upon the application.

In one embodiment, a conductive material 118 may be formed on the thin conformal copper layer 108 (FIG. 1f. In one embodiment, the conductive material 118 may be formed by at least one of an electroless deposition process and an electroplating process, as are known in the art. In yet another embodiment, the conductive material 118 may be formed by the continued deposition of Cu via CVD or ALD, per the outlined procedures abovementioned. In one embodiment, the conductive material 118 may comprise copper and may comprise a conductive trace within a microelectronic device.

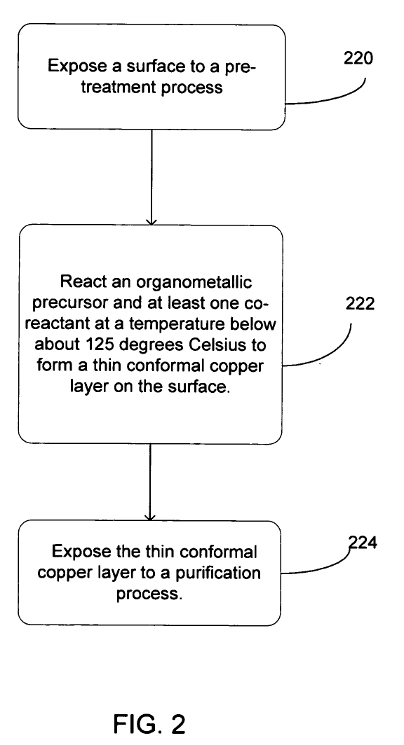

FIG. 2 depicts a flow chart of a process of forming a thin conformal copper layer according to an embodiment of the present invention. At step 220, a surface may be exposed to a pre-treatment process, similar to the various pretreatments of the surface described previously herein. At step 222, an organometallic precursor and at least one co-reactant may be reacted at a temperature below about 125 degrees Celsius to form a thin conformal copper layer on the surface. At step 224, the thin conformal copper layer 108 may be exposed to a purification process, similar to the various purification processes described previously herein.

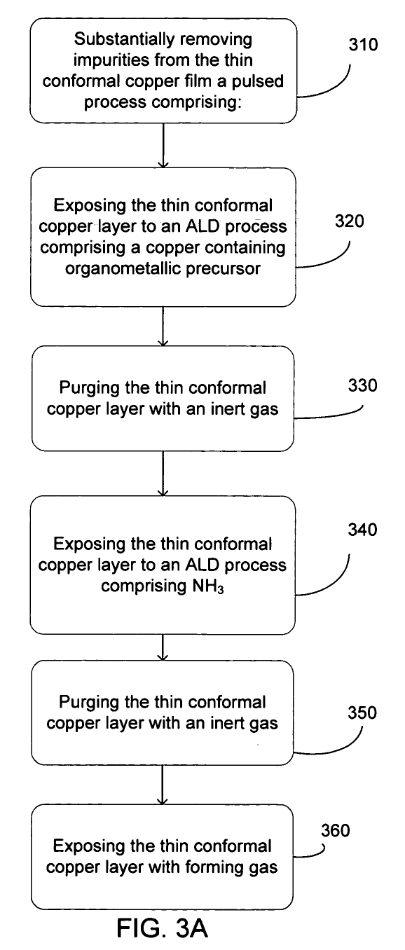

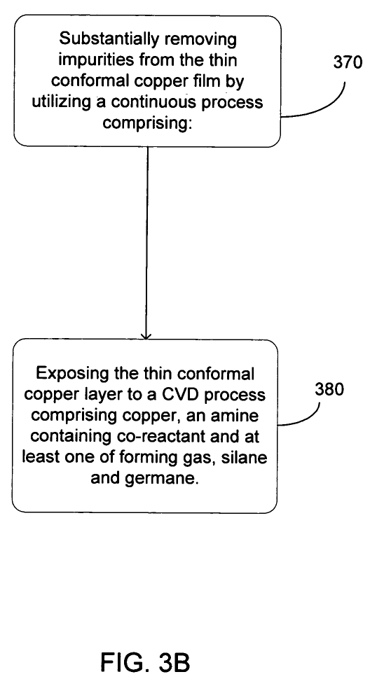

FIGS. 3a-3b depict flow charts of purification processes according to to embodiments of the present invention. Referring to FIG. 3a, at step 310, impurities may be substantially removed from the thin conformal copper film by utilizing a pulsed process. The pulsed process may comprise, beginning at step 320, exposing the thin conformal copper layer to an ALD process comprising a copper containing organometallic precursor, at step 330, purging the thin conformal copper layer with an inert gas, at step 340, exposing the thin conformal copper layer to an ALD process comprising NH₃, purging the thin conformal copper layer with an inert gas at step 350, and at step 360, exposing the thin conformal copper layer to forming gas.

FIG. 3b depicts another embodiment of a purification process according to methods of the present invention. Referring to FIG. 3b, at step 370, impurities may be substantially removed from the thin conformal copper film by utilizing a continuous process. The continuous process may comprise, beginning at step 380, exposing the thin conformal copper layer to a CVD process comprising a copper, an amine containing co-reactant and at least one of forming gas, silane and germane, for example.

As described above, the methods of the present invention enable formation of an extremely thin copper film that is substantially conformal and continuous. By forming the thin copper film at a low temperature, as well as utilizing precursors that are substantially free of fluorine, such failure mechanisms as copper agglomeration and delamination may be substantially eliminated. Thus the reliability of microelectronic devices utilizing the thin conformal copper layer formed according to the methods of the present invention are greatly enhanced.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that the fabrication of a conductive layers within a substrate, such as a silicon substrate, to manufacture a microelectronic device is well known in the art. Therefore, it is appreciated that the Figures provided herein illustrate only portions of an exemplary microelectronic device that pertains to the practice of the present invention. Thus the present invention is not limited to the structures described herein.

What is claimed is:

1. A method comprising:
forming a thin conformal copper layer on a surface by utilizing a formation temperature below about 125 degrees Celsius.

2. The method of claim 1 wherein forming the thin conformal copper layer further comprises wherein the thin conformal copper layer is substantially continuous.

3. The method of claim 1 wherein forming the thin conformal copper layer further comprises wherein the thin conformal copper layer comprises a roughness between about 0.3 and 3 nm.

4. The method of claim 1 wherein forming the thin conformal copper layer comprises forming the thin conformal copper layer by utilizing at least one organometallic precursor.

5. The method of claim 1 wherein forming the thin conformal copper layer comprises reacting at least one organometallic precursor with at least one co-reactant.

6. The method of claim 5 wherein reacting the at least one organometallic precursor comprises reacting at least one copper containing amidinate comprising DMAPA, DMOPA, DMAEO, EMAPA, BTMSAPA, HPA, DMAtBA, DMABTMSA, MOPA, EtOPA, BOPA, MOBA, MOTMSA and combinations thereof.

7. The method of claim 5 wherein reacting the at least one organometallic precursor comprises reacting at least one of a copper containing amino-alkoxy compound and a copper containing Pyrazolato compound.

8. The method of claim 5 wherein reacting at least one co-reactant comprises reacting at least one of an amine containing co-reactant.

9. The method of claim 8 wherein reacting at least one of an amine containing co-reactant comprises reacting at least one of NH₃, NEt₃, HNEt₂, tBu₂NH.

10. The method of claim 5 wherein reacting at least one co-reactant comprises reacting at least one of B₂H₆, SiH₄, GeH₄, SnH₄, AlH₃ and H₂.

11. The method of claim 1 wherein forming the thin conformal copper layer further comprises wherein the thin conformal copper layer comprises a thickness below about 30 nanometers.

12. The method of claim 1 wherein forming the thin conformal copper layer further comprises wherein the thin conformal copper layer is formed in a process gas mixture that is substantially free of flourine.

13. The method of claim 1 further comprising wherein the thin conformal copper layer is formed by at least one of a CVD and an ALD process.

14. The method of claim 1 wherein forming the thin conformal copper layer further comprises wherein the thin conformal copper layer comprises between about 90 and 99 percent copper.

15. A method comprising:
forming a barrier layer within at least one opening of a dielectric; and
forming a thin conformal copper layer on the barrier layer by utilizing a formation temperature below about 125 degrees Celsius.

16. The method of claim 15 wherein forming the barrier layer further comprises exposing the barrier layer to at least one organometallic precursor and at least one co-reactant during the formation of the barrier layer.

17. The method of claim 16 wherein the at least one co-reactant comprises at least one of NH₃, NEt₃, HNEt₂, tBuNH₂, B₂H₆, SiH₄, GeH₄, SnH₄, AlH₃ and H₂.

18. The method of claim 16 wherein the barrier layer is doped by at least one of the at least one co-reactant and the at least one organometallic precursor.

19. The method of claim 16 wherein the barrier layer is functionalized by at least one of the at least one co-reactant and the at least one organometallic precursor.

20. The method of claim 15 wherein forming the barrier layer further comprises exposing the barrier layer to at least one of NH₃, NEt₃, HNEt₂, tBU₂NH, B₂H₆, SiH₄, GeH₄, SnH₄, AlH₃ and H₂ prior to the formation of the thin conformal copper layer.

21. The method of claim 19 wherein the surface of the barrier layer is chemically modified by the at least one co-reactant.

22. The method of claim 15 further comprising substantially removing impurities from the thin conformal copper layer by exposing the thin conformal copper layer to a CVD process comprising copper, ammonia and at least one of H₂, SiH₄, B₂H₆, GeH₄, SnH₄, AlH₃ CO and forming gas.

23. The method of claim 15 further comprising substantially removing impurities from the thin conformal copper layer by:
exposing the thin conformal copper layer to an ALD process comprising a copper containing precursor;
purging the thin conformal copper layer with an inert gas;
exposing the thin conformal copper layer to an ALD process comprising an amine containing co-reactant;
purging the thin conformal copper layer with the inert gas; and
exposing the thin conformal copper layer to forming gas.

24. The method of claim 15 wherein the at least one opening in the dielectric comprises a portion of a damascene structure.

25. The method of claim 15 further comprising forming a conductive material on the thin conformal copper layer, wherein the conductive material is formed by at least one of electroless deposition and electroplating.

26. A structure comprising:
a thin conformal copper layer disposed on a surface, wherein the thin conformal copper layer comprises between about 90 to about 99 percent copper and a thickness below about 20 nanometers.

27. The structure of claim 26 wherein the thin conformal copper layer comprises a thickness above about 2 nm that is substantially continuous.

28. The structure of claim 26 wherein the thin conformal copper layer comprises a roughness between about 0.3 to about 3 nanometers.

29. The structure of claim 26 wherein the thin conformal copper layer comprises a ratio of a bottom thickness to a sidewall thickness to a top thickness of a feature of about 1:1:1.

30. The structure of claim 26 wherein the thin conformal copper layer comprises between about 2-5 percent carbon, about 1-2 percent nitrogen and about 1 percent oxygen.

31. The structure of claim 26 wherein the thin conformal copper layer is substantially free of fluorine.

32. The structure of claim 26 wherein the surface comprises a barrier layer disposed within at least one opening of a dielectric layer.

33. The structure of claim 31 further comprising a conductive material disposed on the thin conformal copper layer.
